(19) United States
(12) Patent Application Publication
(10) Pub. No.: US 2006/0137970 A1
(43) Pub. Date: Jun. 29, 2006

(54) Shield unit for TiN sputtering apparatus, method of coating the same, and sputtering method

(75) Inventor: Kyo-Jun Ahn, Yeoju-gun (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: DongbuAnam Semiconductor Inc.

(21) Appl. No.: 11/317,703

(22) Filed: Dec. 23, 2005

(30) Foreign Application Priority Data
Dec. 29, 2004 (KR) 10-2004-0115165

(51) Int. Cl. C23C 14/00

(52) U.S. Cl. 204/192.15; 204/298.11

(57) ABSTRACT

The present invention relates to a shield unit for a titanium nitride (TiN) sputtering apparatus that can reduce or prevent generation of unwanted particles. An exemplary shield unit for the sputtering apparatus according to an embodiment of the present invention includes an upper shield having a titanium (Ti) coating on an upper portion thereof and (optionally) an aluminum (Al) coating on a lower portion thereof, and a lower shield having a titanium (Ti) on at least part of a sidewall thereof and (optionally) an aluminum (Al) on a bottom surface thereof.

### CROSS-REFERENCE TO RELATED APPLICATION

This application claims priority to and the benefit of Korean Patent Application No. 10-2004-0115165, filed in the Korean Intellectual Property Office on Dec. 29, 2004, the entire contents of which are incorporated herein by reference.

### BACKGROUND OF THE INVENTION

(a) Field of the Invention

The present invention relates to a shield unit for a titanium nitride (TiN) sputtering apparatus, a method of coating the same, and a sputtering method using the same. More particularly, the present invention relates to a shield for a titanium nitride (TiN) sputtering apparatus that can prevent falling of foreign particles.

(b) Description of the Related Art

Physical vapor deposition (PVD) is a process for forming a layer having a predetermined composition and crystal structure on a substrate by evaporating a metal material by energy such as an arc, heat, or an electron beam, and activating the evaporated metal material with plasma energy or ion beam energy. PVD methods can be classified into methods of evaporation of the metal material, methods involving an atmosphere for coating, and a method of enhancing metal reactivity.

In a chamber for a sputtering method, which is one of the reactivity-enhancing PVD methods, a shield is located at a portion that is exposed to plasma. The shield is reused, and it stabilizes the chamber and helps to optimize the plasma condition(s).

As shown in FIG. 1, a sputtering apparatus for titanium nitride (TiN) includes a chamber body 1, an electrostatic chuck 3 that is located in the chamber body 1 for loading a wafer 2 thereon, a sputtering target 4 provided in an upper position in the chamber body 1, and upper and lower shields 5 and 6 that can protect the various parts of the chamber 1.

The upper shield 5 and the lower shield 6, as shown in FIG. 2 and FIG. 3, have circular cross-sections, and are surface-treated using bead particles (e.g., by striking the shield surface[s] with Al₂O₃ particles propelled by pressurized air or nitrogen gas) so as to have an average roughness (Ra) of about 200 μm/inch. They cover the parts of the chamber 1 that are exposed to plasma and may have particles deposited thereon. The value of the roughness average (Ra) can be changed.

In the titanium nitride (TiN) sputtering apparatus, argon (Ar) gas and nitrogen gas are mixed and a plasma formed therefrom to help form a titanium nitride (TiN) layer. The sputtered titanium nitride (TiN) layer may be deposited on the upper shield 5 and the lower shield 6 that protect the wafer 2 and the interior part of the chamber body 1.

As the quantity of titanium nitride (TiN) that is deposited on the upper shield 5 and the lower shield 6 increases, the tendency for it to separate or part therefrom increases because of its poor adhesion characteristics. The titanium nitride (TiN) deposited on the upper shield 5 and the lower shield 6 may part or separate therefrom because of stress that may be caused by a high process temperature. Consequently, separated particles of titanium nitride (TiN) may fall on the wafer 2 and contaminate it, causing defects on the wafer and reduced yields as a result.

If the number of uses of the shields is reduced, the fall-out of the titanium nitride (TiN) may be suppressed, but this may cause a reduction of productivity (e.g., equipment operational efficiency or “uptime”) and an increased cost of the sputtering process.

In one approach for preventing such a problem as described above, in order to enhance adhesion of the TiN layer, aluminum (Al) particles are coated on the entire surface of the shield by an arc-spray method so that the average roughness (Ra) of the surface of the shield may be 500-800 μm/inch. However, in this approach, the aluminum (Al) particles on the shield surface may drop on the substrate during a pumping process for evacuating the chamber, so as to become a defect source. That is, the aluminum (Al) particles on the shield surface may cause defects under typical processing conditions.

The above information disclosed in this Background section is only for enhancement of understanding of the background of the invention, and therefore, it may contain information that does not form prior art or other information that is already known in this or any other country to a person of ordinary skill in the art.

### SUMMARY OF THE INVENTION

The present invention has been made in an effort to provide a shield unit for a titanium nitride (TiN) sputtering apparatus, a method of coating the same, and a sputtering method using the same, having advantages of reducing or preventing TiN particles by a shield-coating method using titanium (Ti) and aluminum (Al).

An exemplary shield unit for a titanium nitride (TiN) sputtering apparatus (e.g., a sputtering apparatus adapted to sputter titanium nitride) according to an embodiment of the present invention comprises a shield unit used for protecting an interior part of a chamber in a titanium nitride (TiN) sputtering apparatus, wherein the shield unit includes an upper shield coated with titanium (Ti) at least on an upper portion thereof and (optionally) coated with aluminum (Al) on a lower portion thereof, and a lower shield coated with titanium (Ti) at least on a sidewall thereof and (optionally) coated with aluminum (Al) on a bottom portion thereof.

In a further embodiment, an average roughness (Ra) of a surface coated with the titanium (Ti) may be about 400±40 μm/inch. In addition, an average roughness (Ra) of a surface coated with the aluminum (Al) may be about 500±50 μm/inch.

An exemplary method of coating a shield unit for a titanium nitride (TiN) sputtering apparatus (e.g., a sputtering apparatus adapted to sputter titanium nitride) according to another embodiment of the present invention includes coating an upper shield with titanium at least on an upper portion thereof and (optionally) with aluminum on a lower portion thereof; and coating a lower shield with titanium on an interior sidewall thereof and (optionally) with aluminum on an interior bottom surface thereof. The method may further comprise disposing the upper shield in a sputtering chamber of the apparatus, and disposing the lower shield below at least part of the upper shield in the sputtering chamber.

As for the shield unit described above, the titanium may have an average roughness of about 400±40 μm/inch, and the aluminum may have an average roughness of about 500±50 μm/inch.

An exemplary method for sputtering titanium nitride (TiN) according to the present invention may include preparing a sputtering apparatus having a shield unit therein, the shield unit including an upper shield and a lower shield, the upper shield having a titanium coating on an upper portion thereof and (optionally) an aluminum coating on a lower portion thereof, the lower shield having a titanium coating on an interior sidewall thereof and (optionally) an aluminum coating on an interior bottom surface thereof; and depositing the titanium nitride in the sputtering apparatus.

In a further embodiment, the titanium nitride (TiN) may provide a (diffusion) barrier function for a metal line in a semiconductor device.

As for the shield unit and method described above, the surface with the titanium coating may have an average roughness of about 400±40 μm/inch, and the surface with the aluminum coating may have an average roughness of about 500±50 μm/inch.

### BRIEF DESCRIPTION OF THE DRAWINGS

FIG. 1 is a configuration diagram showing a conventional apparatus for sputtering titanium nitride (TiN).

FIG. 2 is a diagram showing an upper shield of a conventional apparatus for sputtering titanium nitride (TiN).

FIG. 3 is a diagram showing a lower shield of a conventional apparatus for sputtering titanium nitride (TiN).

FIG. 4 is a cross-sectional diagram showing an upper shield of an apparatus for sputtering titanium nitride (TiN) according to an exemplary embodiment of the present invention.

FIG. 5 is a cross-sectional diagram showing a lower shield of an apparatus for sputtering titanium nitride (TiN) according to an exemplary embodiment of the present invention.

### DETAILED DESCRIPTION OF THE EMBODIMENTS

An exemplary embodiment of the present invention will hereinafter be described in detail with reference to the accompanying drawings. The above and other objects, features, and advantages of the present invention will become apparent from the following description of the preferred embodiment.

FIG. 4 is a cross-sectional diagram showing an upper shield of an apparatus for sputtering titanium nitride (TiN) according to an exemplary embodiment of the present invention.

As shown in FIG. 4, the upper shield 5 in the titanium nitride (TiN) sputtering chamber according to an exemplary embodiment of the present invention can be divided into an upper portion and a lower portion. The upper portion of the upper shield 5 may be coated with titanium 71, and the titanium coating 71 may have an average roughness (Ra) of about 400±40 μm/inch. The lower portion of the upper shield 5 may be coated with aluminum 72, and the aluminum coating 72 may have an average roughness (Ra) of about 500±50 μm/inch. However, the upper shield 5 may simply be coated with titanium alone.

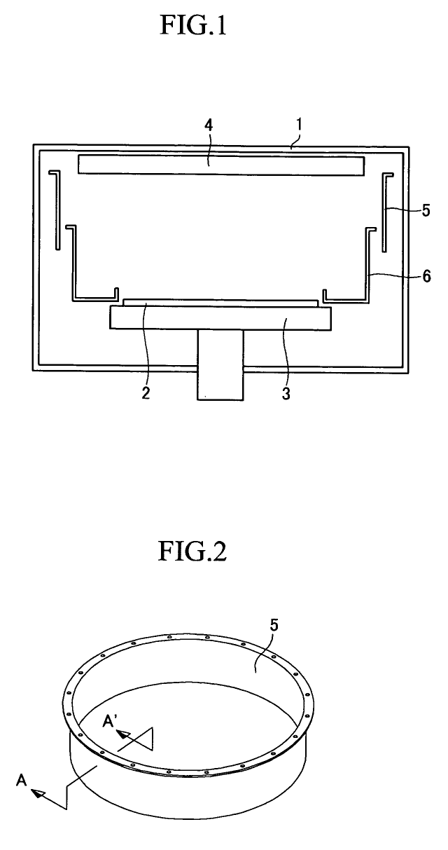

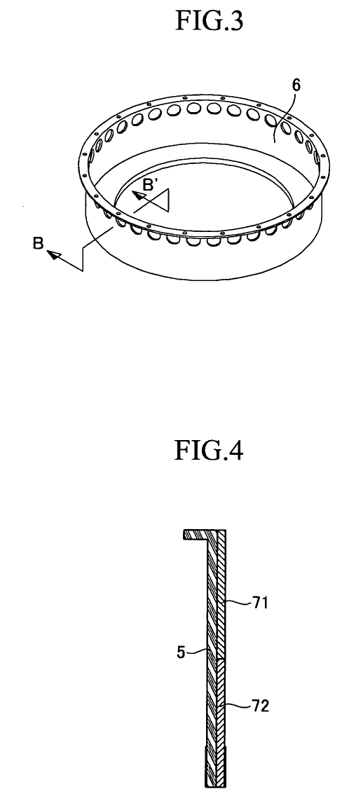

Furthermore, the upper shield 5 may have a circumference and a height, and the upper portion of the upper shield 5 may comprise the uppermost 20-90%, 30-80%, or 40-70% of the height of the upper shield 5. In one embodiment, the upper portion of the upper shield 5 comprises the portion of the upper shield 5 positioned above the lower shield 6 (see, e.g., FIG. 1).

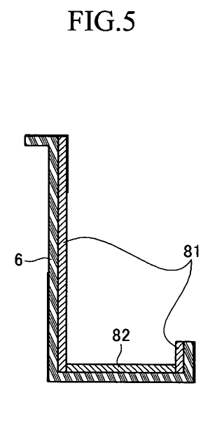

FIG. 5 is a cross-sectional diagram showing a lower shield of an apparatus for sputtering titanium nitride (TiN) according to an exemplary embodiment of the present invention.

In addition, the lower shield 6 can be divided into a sidewall (which may comprise an outer sidewall and an inner sidewall) and a bottom surface. Part or all of the sidewall (e.g., the outer and/or inner sidewall) of the lower shield 6 may be coated with titanium 81, and the titanium coating 81 may have an average roughness (Ra) of about 400±40 μm/inch. The bottom surface of the lower shield 6 may be coated with aluminum 82, and the aluminum coating 82 may have an average roughness (Ra) of about 500±50 μm/inch. Alternatively, the lower shield 6 may simply be coated with titanium alone.

Furthermore, the outer sidewall of the lower shield 6 may have a circumference and a height, and the upper portion of the outer sidewall of the lower shield 6 may comprise the uppermost 20-90%, 30-80%, or 40-70% of the height of the outer sidewall of the lower shield 6. In one embodiment, the upper portion of the outer sidewall of the lower shield 6 comprises the portion of the outer sidewall of the upper shield 5 above the inner sidewall of lower shield 6 (see, e.g., FIG. 1, where the inner sidewall of lower shield 6 is the sidewall closest to wafer 2 and/or electrostatic chuck 3).

An exemplary shield for a titanium nitride (TiN) sputtering apparatus and an exemplary method of coating a substrate with TiN that uses such a structure described above will now be described.

The titanium (Ti) and aluminum (Al) coated on the surface of the upper shield 5 and the lower shield 6 may increase the surface adhesion of TiN, so the separation or generation of TiN particles can be reduced or prevented. The method of coating titanium and (optionally) aluminum on a portion of a shield surface may comprise arc-spraying or other spray coating or liquid and/or vapor deposition method providing an average surface roughness of from 20 μm/inch to 1500 μm/inch, or any range of values therein (e.g., 50 μm/inch to 1000 μm/inch, 100 μm/inch to 800 μm/inch, etc.).

As described elsewhere herein, the upper shield 5 in the chamber can be divided into an upper portion and a lower portion. The upper portion of the upper shield 5 may be coated with titanium 71 having an average roughness (Ra) of about 400±40 μm/inch. The lower portion of the upper shield 5 may be coated with aluminum 72 having an average roughness (Ra) of about 500±50 μm/inch.

In addition, the lower shield 6 can be divided into a sidewall and a bottom surface. The sidewall of the lower shield 6 may be coated with titanium 81 so as to have an average roughness (Ra) of about 400±40 μm/inch. The bottom surface of the lower shield 6 may be coated with aluminum 82 so as to have an average roughness (Ra) of about 500±50 μm/inch. Consequently, the respective method of coating titanium and (optionally) aluminum by, e.g., arc-spraying the metal on each (respective) portion of a shield surface (upper or lower) can reduce or prevent the generation of fallout particles and contamination of the wafers by such particles.

A sputtering apparatus having a shield according to an exemplary embodiment of the present invention can reduce or prevent generation of defects that may be caused by TiN particles separating or falling from the shield, so a titanium nitride (TiN) layer having good qualities can be deposited using the sputtering apparatus. The titanium nitride (TiN) may be used as a (diffusion) barrier layer in a metal line in a semiconductor device, for example.

As described above with reference to an exemplary embodiment, the shield surface may be classified into a general portion and a rougher portion, and the portions of the shield are respectively coated with titanium (Ti) and aluminum (Al). Therefore the shield can have a good adhesion characteristics, so it can reduce or prevent TiN particles separating or falling from the shield. Furthermore, although the present invention enjoys particular advantage in an apparatus adapted for sputtering TiN, the present invention can be used in any apparatus for sputtering any metal or other conductor (e.g., Ti, Al, Ta, TaN, etc.).

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A shield unit for protecting an interior part of a chamber in a sputtering apparatus, the shield unit comprising:
an upper shield having a titanium (Ti) coating on an upper portion thereof; and
a lower shield having a titanium (Ti) coating on at least part of a sidewall thereof.

2. The shield unit of claim 1, wherein an average roughness of the titanium coatings is about 400±40 μm/inch.

3. The shield unit of claim 1, wherein the upper shield further includes an aluminum (Al) coating on a lower portion thereof.

4. The shield unit of claim 1, wherein the lower shield further includes an aluminum (Al) coating on a bottom portion thereof.

5. The shield unit of claim 3, wherein an average roughness of the aluminum coating is about 500±50 μm/inch.

6. The shield unit of claim 4, wherein an average roughness of the aluminum coating is about 500±50 μm/inch.

7. An apparatus adapted to sputter titanium nitride, comprising a sputtering chamber and the shield unit of claim 1 therein.

8. A method of coating a shield unit for a sputtering apparatus, the shield unit comprising an upper shield and a lower shield, the method comprising:
coating an upper portion of the upper shield with titanium; and
coating at least part of an interior sidewall of the lower shield with titanium.

9. The method of claim 8, wherein the titanium coatings have an average roughness of about 400±40 μm/inch.

10. The method of claim 8, further comprising coating a lower portion of the upper shield with aluminum (Al).

11. The method of claim 8, further comprising coating a bottom portion of the lower shield with aluminum (Al).

12. The method of claim 10, wherein the aluminum coating has an average roughness of about 500±50 μm/inch.

13. The method of claim 11, wherein the aluminum coating has an average roughness of about 500±50 μm/inch.

14. A method for sputtering titanium nitride, comprising:
placing a substrate in a sputtering apparatus having a shield unit therein, the shield unit comprising an upper shield and a lower shield, the upper shield having a titanium coating on an upper portion thereof, and the lower shield having a titanium coating on at least part of an interior sidewall thereof; and
depositing the titanium nitride on the substrate in the sputtering apparatus.

15. The method of claim 14, wherein a barrier layer for a metal line on the substrate comprises at least part of the titanium nitride.

16. The sputtering method of claim 14, wherein an average roughness of a surface having the titanium coating thereon is about 400±40 μm/inch.

17. The method of claim 14, wherein the upper shield further includes an aluminum (Al) coating on a lower portion thereof, and the lower shield further includes an aluminum (Al) coating on a bottom portion thereof.

18. The method of claim 17, wherein an average roughness of a surface having the aluminum coating thereon is about 500±50 μm/inch.

19. The method of claim 14, further comprising forming the metal line on at least part of the titanium nitride.
